(19) United States
(12) Patent Application Publication
(10) Pub. No.: US 2005/0185365 A1
(43) Pub. Date: Aug. 25, 2005

(54) Display apparatus

(75) Inventors: Koichi Yamaguchi, Saitama (JP); Shota Kida, Saitama (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/040,034

(22) Filed: Jan. 24, 2005

(30) Foreign Application Priority Data
Feb. 6, 2004 (JP) 2004-31255

(51) Int. Cl. H05K 5/00; H05K 7/00

(52) U.S. Cl. 361/679

(57) ABSTRACT

In a display apparatus, a connector board having a check connector electrically connected to a service terminal of a main circuit board is disposed separately from a main circuit board. A connector window is formed in a back cover at a position facing the check connector on the connector board such that a dedicated plug can be fitted to the check connector through the connector window. A lid member is attached to the connector window. Rewrite of data and programs in the main circuit board is performed by fitting the dedicated plug to the check connector after removing the lid member.

### CROSS-REFERENCE TO RELATED APPLICATIONS

This application is based upon and claims the benefit of priority from the prior Japanese Patent Application No. 2004-31255, filed on Feb. 6, 2004; the entire contents of which are incorporated herein by reference.

### BACKGROUND OF THE INVENTION

1. Field of the Invention

The present invention relates to a display apparatus in which a connector board associated with a main circuit board for checking and/or rewriting various data and programs can be disposed in any desired position.

2. Description of the Related Art

In display apparatus for television receivers, etc., cathode ray tubes (CRT's) are widely used as units for displaying received signals. Recently, display devices using plasma displays and liquid crystal displays (referred to as “flat display panels” hereinafter) have been practiced in place of CRT's.

A display apparatus using a flat display panel has a small depth dimension. Therefore, such a display apparatus can be mounted to a wall surface or placed on a floor, etc. in a state closely positioned against the wall surface. Also, to reproduce videos and voices based on signals from external units, such as VCR and DVD players, many signal cables extending from those external units are connectable to a display apparatus using a flat display panel. A connector structure for connecting those many signal cables is designed so as not to impair an aesthetic appearance of the display apparatus.

A display apparatus designed in consideration of an aesthetic appearance is disclosed, for example, in Japanese published patent application No. 2001-230989 (referred to as Reference 1 hereinafter), on page 4 and FIG. 2. In the display apparatus of Reference 1, a group of connectors for connection to signal cables extending from external units are provided in a part of a back cover. The signal cables connected to the group of connectors are covered by a cover or the like such that the signal cables will not be exposed to the surface of the back cover and will not impair the aesthetic appearance.

On the other hand, recent television receivers are able to receive and reproduce a broadcast based on analog TV signals and a broadcast based on digital TV signals. Therefore, a recent television receiver includes a circuit board on which are constructed an analog signal processing circuit for processing the analog TV signals and a digital signal processing circuit for processing the digital TV signals. The digital signal processing circuit contains data and control programs for digital signal processing.

The circuit board is provided with service terminals used to, for example, check the analog and digital signal processing circuits and rewrite the data and the control programs. The operation check and the rewrite of the data and the control programs are performed by connecting, to respective service terminals, a measuring jig for the operation check, a jig for the rewrite of the data and the control programs, etc.

Further, because the service terminals are used when the display device is manufactured and when a serviceman makes a check, the service terminals are housed in a back cover to keep users away from easy access to them.

In the display device disclosed in Reference 1 and designed in consideration of an aesthetic appearance, when the jigs for the check and rewrite are connected to the service terminals provided on the circuit board, users are required to perform troublesome work of removing the signal cables extending from the external units and connected to the connector group in the back cover, and then removing the back cover, thereby causing the circuit board to be exposed. That work of removing the signal cables and the back cover is poor in efficiency and takes a time.

### SUMMARY OF THE INVENTION

Accordingly, it is an object of the present invention to provide a display apparatus in which signal cables used for connection to external units can be connected and put in order with ease, and jigs for a check and rewrite can be connected to service terminals for the check and rewrite with no need of removing the signal cables and a back cover.

The display apparatus of the present invention is featured in comprising a connector board having a connector electrically connected to a service terminal of a main circuit board disposed within a housing in which a display panel is housed; a connector window formed in the housing in facing relation to a mount position of the connector board such that the connector is exposed through the connector window; and a lid member for covering the connector window to conceal the connector.

The above and other objects, features and advantages of the invention will become more clearly from the following referring to the accompanying drawings.

### BRIEF DESCRIPTION OF THE DRAWINGS

FIG. 1 is a perspective view showing the rear side of a display apparatus according to one embodiment of the present invention;

FIG. 2 is a partial perspective view showing a state in which a wiring cover is attached to a back cover of the display apparatus according to one embodiment of the present invention;

FIG. 3 is a partial perspective view showing a cable wiring space in a state in which the wiring cover is detached from the back cover of the display apparatus according to one embodiment of the present invention;

FIG. 4 is a partial perspective view showing a state in which a lid member is removed from a connector window in the back cover of the display apparatus according to one embodiment of the present invention;

FIG. 5A is a perspective view of the lid member fitted to the connector window in the back cover of the display apparatus according to one embodiment of the present invention;

FIG. 5B is a sectional view of the lid member taken along a section line x-x in FIG. 5A;

FIG. 6 is a sectional view showing the positional relationship between the connector window in the back cover of the display apparatus and a connector board mounting connectors thereon in the display apparatus according to one embodiment of the present invention; and

FIG. 7 is a plan view showing the positional relationship between a main circuit board and the connector board in the display apparatus according to one embodiment of the present invention.

### DESCRIPTION OF THE PREFERRED EMBODIMENTS

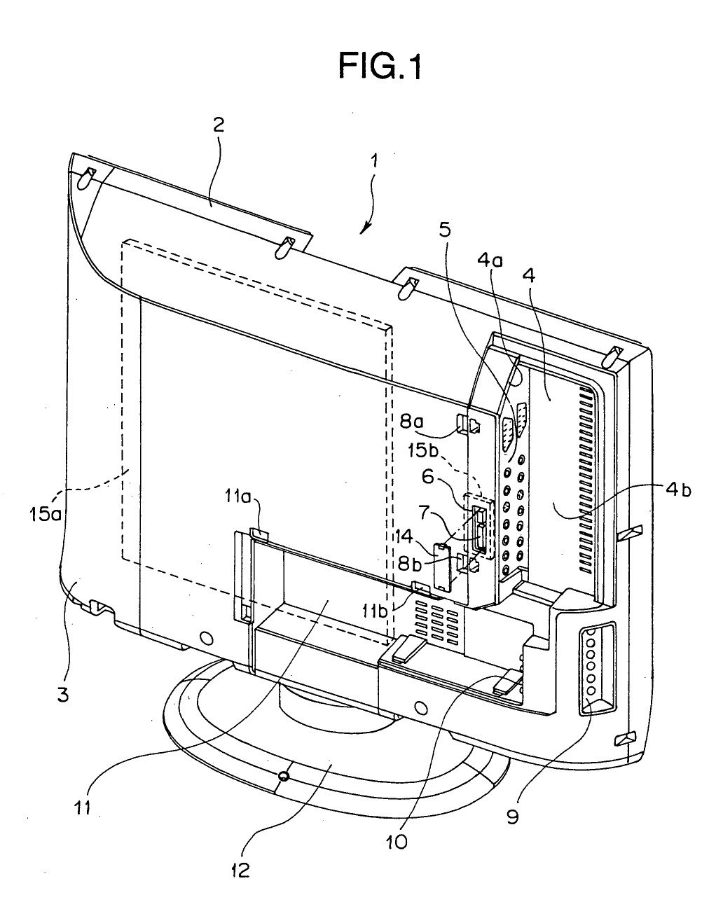

FIG. 1 is a perspective view showing the rear side of a display apparatus according to one embodiment of the present invention. In the following, the display apparatus of the present invention will be described, by way of example, in connection with a television receiver (referred to as a “TV set” hereinafter) employing a flat display panel, e.g., a liquid crystal display or a plasma display.

Referring to FIG. 1, reference numeral 1 denotes a TV set, 2 denotes a front frame, and 3 denotes a back cover. A flat display panel (not shown) is held by the front frame 2. Though not shown, a speaker is disposed on the front side of the front frame 2. Also, the back cover 3 is fitted to the front frame 2. The front frame 2 and the back cover 3 cooperatively constitute a housing for the display apparatus. Thus, the front frame 2 constitutes a front portion of the housing, and the back cover 3 constitutes a rear portion of the housing.

A main circuit board 15a is disposed on the rear side of the flat display panel held by the front frame 2. On the main circuit board 15a, there are formed various so-called circuit blocks constituting the TV set, such as a driving circuit for the flat display panel, a signal processing circuit for executing signal processing of received TV signals, and a memory in which data and control programs for digital signal processing are stored. Further, the main circuit board 15a is provided with service terminals used to check the various circuit blocks and to rewrite the data and the control programs.

A stand 12 is provided at the bottom of the front frame 2 and the back cover 3. The stand 12 supports the TV set 1 in a vertical posture.

In a rear portion of the back cover 3, a cable wiring space 4 and a cable insertion space 11 are formed in a substantially L-shape. The cable wiring space 4 is defined as a recess formed in the rear of the back cover 3 to extend from above toward below on the right side as viewed in the drawing. The cable wiring space 4 has a vertical surface 4a formed perpendicularly to a display surface of the flat display panel, and a parallel surface 4b formed parallel to the display surface of the flat display panel. Looking from above the back cover 3, the cable wiring space 4 has a shape cut substantially in a right-angled section. The cable insertion space 11 is formed in a groove shape extending along a bottom side of the back cover 3, and is communicated with the cable wiring space 4.

A cable connector board 5 is disposed on the vertical surface 4a of the cable wiring space 4. The cable connector board 5 has various female connectors formed therein for connection to signal cables extending from external units. Male connectors attached to fore ends of the signal cables are inserted in corresponding female connectors in the cable connector board 5. Respective portions of the signal cables near the male connectors are disposed in the cable wiring space 4. Further, respective extended portions of the signal cables are routed through the cable insertion space 11 and then led out from the rear of the back cover 3.

Further, an external input terminal area 9 and an external output terminal area 10 are provided in a lower portion of the back cover 3 on the right side as viewed in the drawing. The external input terminal area 9 is exposed at a side of the back cover 3. The external output terminal area 10 is exposed to the inside of the cable insertion space 11.

The signal cables extending from the external units, such as VCR and DVD players, are connected to the cable connector board 5 in the cable wiring area 4 and to the external input terminal area 9. The signal cables for connection to other units are connected to external output terminal area 10.

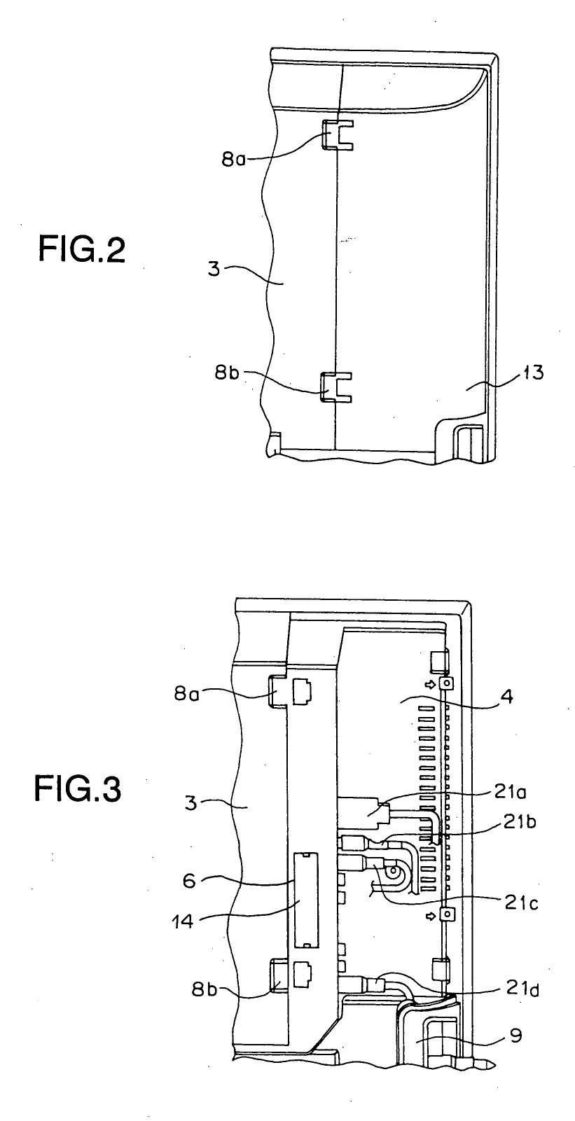

As shown in FIG. 2, a wiring cover 13 is attached to the cable wiring space 4 of the back cover 3. The wiring cover 13 covers the signal cables laid in the cable wiring space 4, and protects the connector portions of the signal cables connected to the cable connector board 5. Also, a cover (not shown) can be likewise attached to the cable insertion area 11. Wiring-cover attachment holes 8a, 8b, shown in the drawing, are used for attaching the wiring cover 13 to the back cover 3. Similarly, attachment holes 11a, 11b, shown in the drawing, are used for attaching the cover that serves to cover the cable insertion area 11.

A connector window 6 is formed in the back cover 3 at a position that is located near the cable wiring space 4 and is covered by the wiring cover 13. Inside the connector window 6, there are disposed a set of check connectors 7 electrically connected to respective service terminals used to execute an operation check of the circuit blocks on the main circuit board 15a and a check and/or rewrite of data and control programs. Dedicated plugs can be fitted to the check connectors 7 through the connector window 6. The dedicated plugs are used to connect a measuring jig for an operation check and a jig for a check and/or rewrite of the data and the control programs, etc. to the adapted check connectors 7.

The connector window 6 has a shape similar to that of the set of check connectors 7 and has a size that is relatively small, but sufficient for allowing insertion of the dedicated plugs for the check and rewrite jigs through the connector window.

A lid member 14 is attached to the connector window 6. As described later, the lid member 14 is of such a structure that the lid member can be easily attached to the connector window 6, but when attempting to remove the lid member, it cannot be detached unless a tool is used. More specifically, the connector window 6 is normally covered by the lid member 14 so as to conceal the check connectors 7 inside the connector window 6. When the dedicated plug is to be fitted through the connector window 6, the lid member 14 is removed by using the tool. Further, since the connector window 6 is formed in a position covered by the wiring cover 13 when the wiring cover 13 is attached in place to cover the cable wiring area 4, the connector window 6 is further concealed by the wiring cover 13.

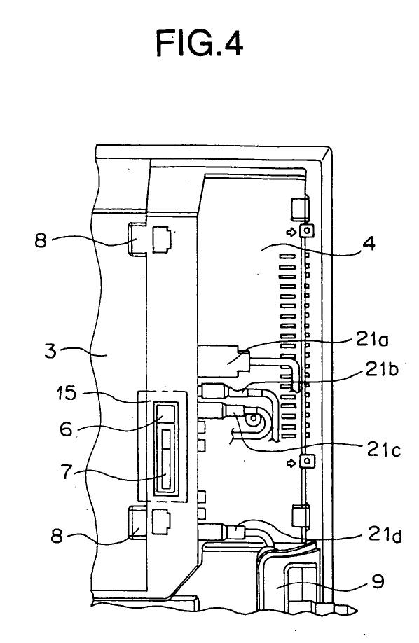

The construction and usage of the check connectors 7 and the connector window 6 will be described below with reference to FIGS. 2 to 4. FIG. 2 shows a state in which the wiring cover 13 is attached to the cable wiring space 4 of the back cover 3, FIG. 3 shows a state in which the wiring cover 13 is detached from the back cover 3, and FIG. 4 shows a state in which the lid member 14 is removed from the back cover 3.

As shown in FIG. 2, the cable wiring space 4 is covered by the wiring cover 13. Projections (not shown) are provided on one lateral side of the wiring cover 13, and the wiring cover 13 is fixed in place by inserting the projections into the wiring-cover attachment holes 8a, 8b while elastically deforming them. The lid member 14, the connector window 6, and the check connectors 7 are concealed by the wiring cover 13 covering the cable wiring space 4. In other words, since the signal cables connected to the cable connector board 5 in the cable wiring space 4 are accommodated in the cable wiring space 4 and concealed by the wiring cover 13, the aesthetic appearance of the back cover 3 is not impaired.

Detaching the wiring cover 13 from the wiring-cover attachment holes 8a, 8b results in the state shown in FIG. 3. In the cable wiring space 4 from which the wiring cover 13 has been removed, a plurality of signal cables 21a, 21b, 21c and 21d connected to respective connectors of the cable connector board 5 are exposed, but the connector window 6 remains concealed by the lid member 14. Accordingly, the check connectors 7 disposed inside the connector window 6 are not exposed and hence are kept from direct access from users.

Then, when the lid member 14 covering the connector window 6 is removed by using a tool, the check connectors 7 disposed inside the connector window 6 are exposed, as shown in FIG. 4, to allow connection of the dedicated plugs to the corresponding check connectors 7. As a result, the dedicated plugs can be fitted to perform an operation check and rewrite of data and programs without removing not only the signal cables 21a, 21b, 21c and 21d connected to the cable connector board 5 in the cable wiring space 4, but also the back cover 3.

Further, when connecting an external unit to the TV set 1, users can easily detach the wiring cover 13. However, the lid member 14 remains attached to the connector window 6 which is positioned in an area concealed by the wiring cover 13, and the lid member 14 cannot be removed unless a tool is used. Accordingly, users can be kept from touching the check connectors 7 disposed inside the connector window 6 or from connecting undesired external units to the check connectors 7.

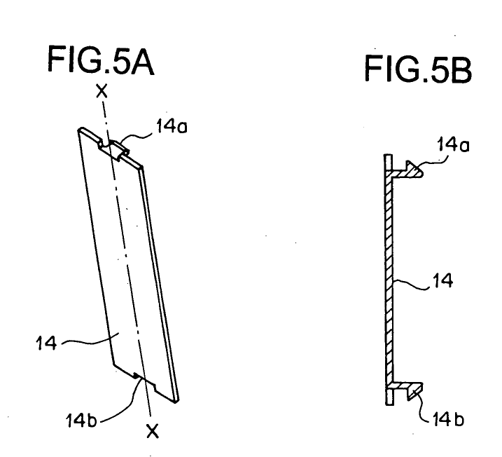

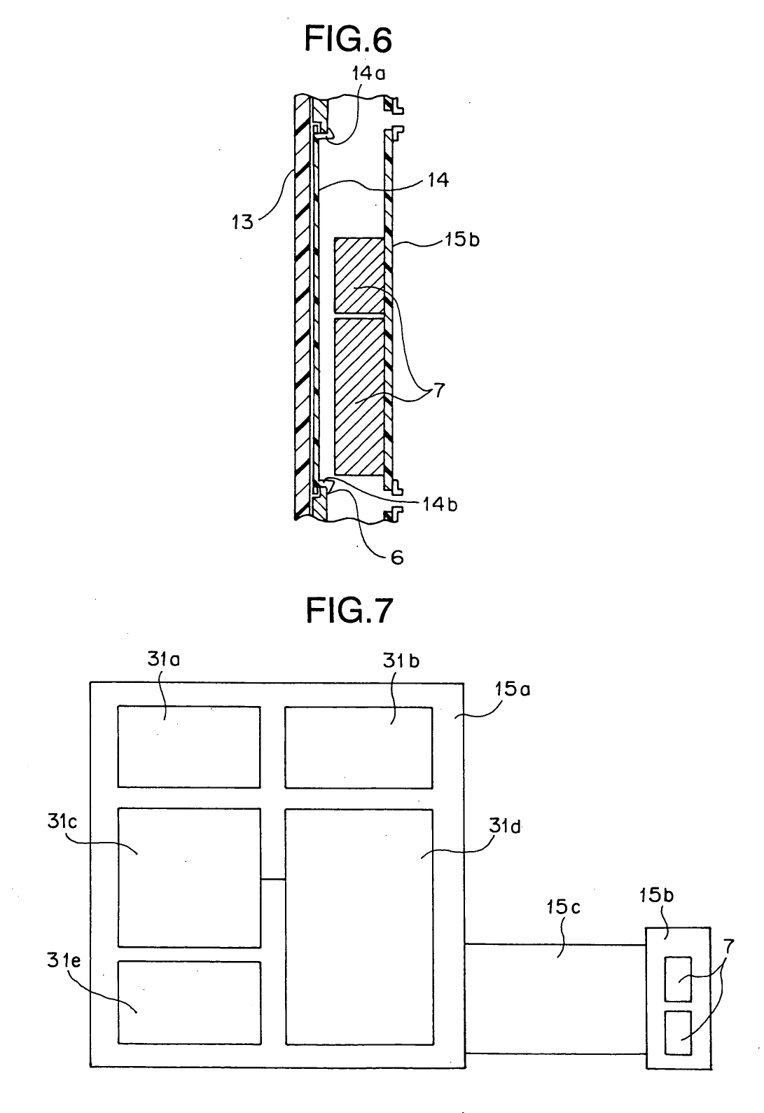

The shape of the lid member 14 fitted to the connector window 6 and the construction of the check connectors 7 mounted in a position facing the connector window 6 will be described below with reference to FIGS. 5 to 7. FIG. 5A is a perspective view of the lid member 14, and FIG. 5B is a sectional view of the lid member 14 taken along a section line x-x in FIG. 5A. FIG. 6 is a sectional view showing the positional relationship between the connector window 6 and the check connectors 7, and FIG. 7 is a plan view showing the positional relationship between the main circuit board 15a and a connector board 15b on which the check connectors 7 are provided.

As shown in FIGS. 5A and 5B, the lid member 14 is formed in shape to be attachable to the connector window 6 that has a substantially rectangular shape and is formed in the back cover 3. Tongues 14a, 14b each formed of an elastic member are provided respectively in opposite short sides of the lid member 14. By fitting the tongues 14a, 14b to the inner side of the connector window 6, the lid member 14 is attached in place such that the surface of the lid member 14 is substantially flush with the surface of an area of the back cover 3 around the connector window 6.

When removing the lid member 14 from the connector window 6, because the lid member 14 is attached with its surface positioned substantially flush with the surface of the back cover 3, the lid member 14 is removed by inserting a specific tool, e.g., a minus driver, into a gap between one of the tongues 14a, 14b of the lid member 14 and the connector window 6, and then flexing the one of the tongues 14a, 14b. Thus, the lid member 14 cannot be removed from the connector window 6 unless a specific tool, e.g., a minus driver, is used. In other words, the lid member 14 can be prevented from being removed by using a coin or the like on the hands of users other than a specific tool, e.g., a minus driver. As a result, undesired access to the check connectors 7 by users can be avoided.

As shown in FIG. 7, the check connectors 7 disposed inside the connector window 6 are mounted on the connector board 15b that is a second board provided separately from the main circuit board 15a mounting a plurality of circuit blocks 31a to 31e thereon. The check connectors 7 on the connector board 15b are electrically connected to a plurality of service terminals (not shown), which are provided on the main circuit board 15a, through a connecting harness 15c formed of a flexible board. The connector board 15b is formed in size smaller than the main circuit board 15a.

The connector board 15b is mounted within the back cover 3 such that the check connectors 7 mounted on the connector board 15b are positioned to face the connector window 6 in the back cover 3. Accordingly, as shown in FIG. 6, surfaces of the check connectors 7 on the side connected to the dedicated plugs are directed toward the connector window 6 and are normally covered by the lid member 14. Then, the lid member 14 is covered by the wiring cover 13. As a result, the back cover 3 can prevent undesired access by users to the check connectors 7 while not impairing the aesthetic appearance.

In the embodiment described above, the connector board 15b mounting the check connectors 7 thereon is disposed in a position that is located near the cable wiring space 4 of the back cover 3 and is concealed by the wiring cover 13. As described above, however, the connector board 15b is formed separately from the main circuit board 15a and has a smaller size. Accordingly, the connector board 15b can be disposed in any desired position within the housing constituted by the front frame 2 and the back cover 3. When the connector board 15b is disposed in a desired position within the housing other than the above-described one, similar advantages can also be obtained by forming the connector window 6 in the housing at a position facing the check connectors 7 on the connector board 15b and attaching the lid member 14, which can be removed only by using a specific tool, to the connector window 6. Thus, the connector board 15b can be disposed in any desired position, and flexibility in design can be increased.

Having described the preferred embodiment of the invention referring to the accompanying drawings, it should be understood that the present invention is not limited to those precise embodiments and various changes and modifications thereof could be made by one skilled in the art without departing from the spirit or scope of the invention as defined in the appended claims.

1. A display apparatus comprising:
a connector board having a connector electrically connected to a service terminal of a main circuit board disposed within a housing in which a display panel is housed;
a connector window formed in said housing in facing relation to a mount position of said connector board such that said connector is exposed through said connector window; and
a lid member covering said connector window to conceal said connector.

2. The display apparatus according to claim 1, wherein a dedicated plug is fitted to said connector on said connector board externally of said housing after removing said lid member.

3. The display apparatus according to claim 1, wherein said housing comprises a front frame with said display panel mounted to a front side of said front frame, a back cover fixed to said front frame, a cable wiring space formed in said back cover and receiving signal cables extending from outer units for connection, and a wiring cover covering said cable wiring space when attached in place, and wherein said connector window is formed in a position covered by said wiring cover.

4. The display apparatus according to claim 1, wherein said lid member can be removed only by using a lid-member removing tool.

5. The display apparatus according to claim 1, wherein said lid member has an elastic member fitted to said connector window and is removed by flexing said elastic member with said lid-member removing tool.

6. The display apparatus according to claim 1, wherein said connector board is formed separately from said main circuit board and has a smaller size than said main circuit board.

7. The display apparatus according to claim 1, wherein said service terminal is used to perform at least one of a check of various circuit blocks provided on said main circuit board, and a check and rewrite of data and programs.
